(19) United States
(12) Patent Application Publication
(10) Pub. No.: US 2005/0133888 A1
(43) Pub. Date: Jun. 23, 2005

(54) Semiconductor packaging substrate

(75) Inventors: Bily Wang, Hsin Chu City (TW); Bill Chang, Hsin Chu City (TW); Yu-Jen Huang, Tai Chung City (TW); Chao-Yen Hsieh, Tai Chung Hsien (TW)

Correspondence Address: TROXELL LAW OFFICE PLLC, SUITE 1404, 5205 LEESBURG PIKE, FALLS CHURCH, VA, 22041, US

(73) Assignee: Harvatek Corporation

(21) Appl. No.: 10/737,905

(22) Filed: Dec. 18, 2003

(51) Int. Cl. H01L 23/495

(52) U.S. Cl. 257/666

(57) ABSTRACT

A package substrate having a chip on a substrate has a die pad on the substrate. The chip is attached on the die pad via ah adhesive. A plurality of gold contacts is distributed on the die pad for electrically connecting to the chip. A plurality of traces is distributed around the die pad to connect to the chip via wires. An adhesive dike is formed between the die pad and the traces to prevent the adhesive from flowing out of the die pad when the chip is attached on the die pad.

### BACKGROUND OF THE INVENTION

1. Field of the Invention

The invention relates to a semiconductor packaging substrate, and more particularly to a packaging substrate in which an adhesive is prevented from flowing out of a die pad during chip attachment.

2. Description of the Related Art

Semiconductor packages such as PDIP, SO, PLCC and QFP use a leadframe as an electric connection and a carrier for an integrated circuit (IC). Leads of PDIP and SO packages are distributed on two opposite sides of the leadframe, while the PLCC and QFP are located in a periphery of the leadframe. Since the peripheral space of IC in the conventional packaging is limited, it may be not enough for high-pin-count (more than 304 pins) packages.

In early 1990s, Motorola, U.S.A, and Citizen, Japan, developed a BGA (ball grid array) packaging that uses an IC substrate to bond the chip thereon via a polymer adhesive, a soft solder material and an alloy. Since the BGA packaging has many advantages over other types of packaging, it has been widely used in the packaging field.

FIG. 1 is a partial top view of a conventional packaging substrate. A package substrate 10b has a die pad 12, a plurality of traces 16, and a plurality of gold contacts 18 respectively at tips of the traces 16. The die pad 12 is an electrically conductive sheet connected to a reference voltage 17. The traces 16 are distributed around the die pad 12. The gold contacts 18 are formed on the die pad 12 for electrically connecting to the chip 14. The chip 14 is attached on the die pad 12 and connects to the gold contacts 18 via wires 13 on the chip 14.

FIG. 2 is a cross-sectional view of FIG. 1. In an integrated circuit packaging, the chip 14 is attached onto the die pad 12 of the substrate 10b via an adhesive 15, this process being called a die attaching process. The adhesive 15 is preferably an epoxy resin. When the integrated chip 14 is fixed on the die pad 12, a circuit of the chip 14 connects to the gold contacts 18 on the substrate 12 via the wires 13 by wire bonding technology. The electrical conductivity of the wires 13 allows an electrical connection between the circuit of the chip 14 and the substrate 10b.

FIG. 2 is a cross-sectional view of FIG. 1. While the chip 14 is being attached onto the die pad 12, the adhesive 15 is often applied on the die pad 12 and is blanketed with a heated nitrogen. The adhesive 15 always flows out of the die pad 12, adversely affecting the conductivity of the gold contacts 18 and the reliability of the packaging.

### SUMMARY OF THE INVENTION

It is therefore an object of the invention to provide a packaging substrate in which an adhesive is prevented from flowing out of a die pad during chip attachment to affect adversely the conductivity of gold contacts on the substrate.

In order to achieve the above and other objectives, the packaging substrate of the invention includes a die pad on the substrate for a chip to attach thereon via an adhesive. A plurality of traces, each with a gold contact at a tip thereof, is distributed around the die pad. An adhesive dike is formed between the die pad and the traces to prevent the adhesive from flowing out of the die pad when the chip is attached on the die pad.

The arrangement of the adhesive dikes prevents the adhesive from flowing out of the die pad, so that the conductivity of the gold contacts and the reliability of the packaging are not adversely affected.

To provide a further understanding of the invention, the following detailed description illustrates embodiments and examples of the invention, this detailed description being provided only for illustration of the invention.

### BRIEF DESCRIPTION OF THE DRAWINGS

The drawings included herein provide a further understanding of the invention. A brief introduction of the drawings is as follows:

FIG. 1 is a partial top view of a conventional semiconductor packaging substrate;

FIG. 2 is a cross-sectional view of FIG. 1;

FIG. 3 is a top view of a semiconductor packaging substrate according to one embodiment of the invention; and

FIG. 4 is a cross-sectional view of FIG. 3.

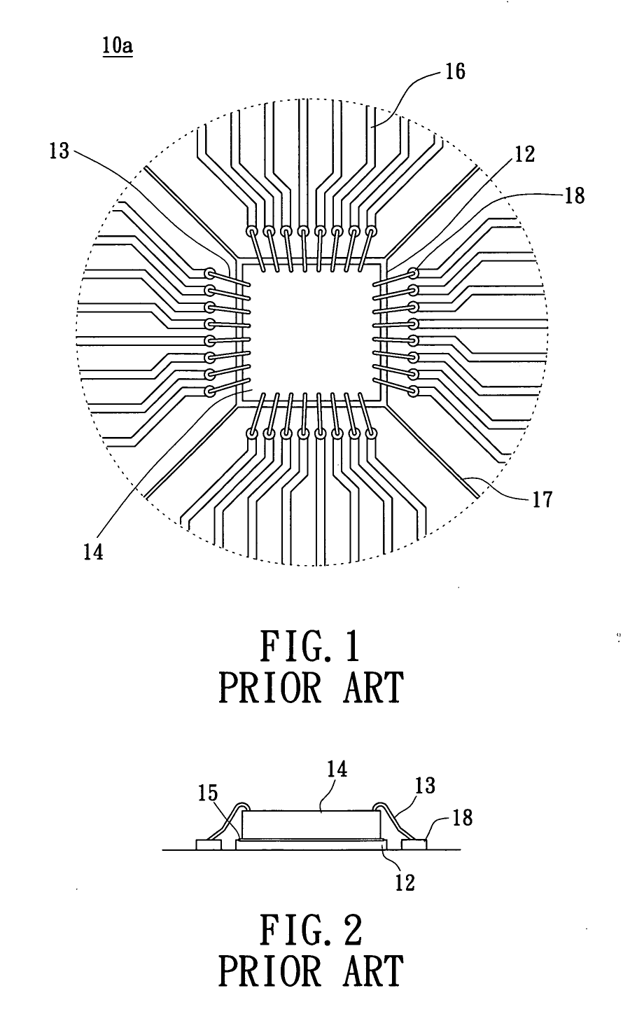

### DETAILED DESCRIPTION OF THE EMBODIMENTS

Wherever possible in the following description, like reference numerals will refer to like elements and parts unless otherwise illustrated.

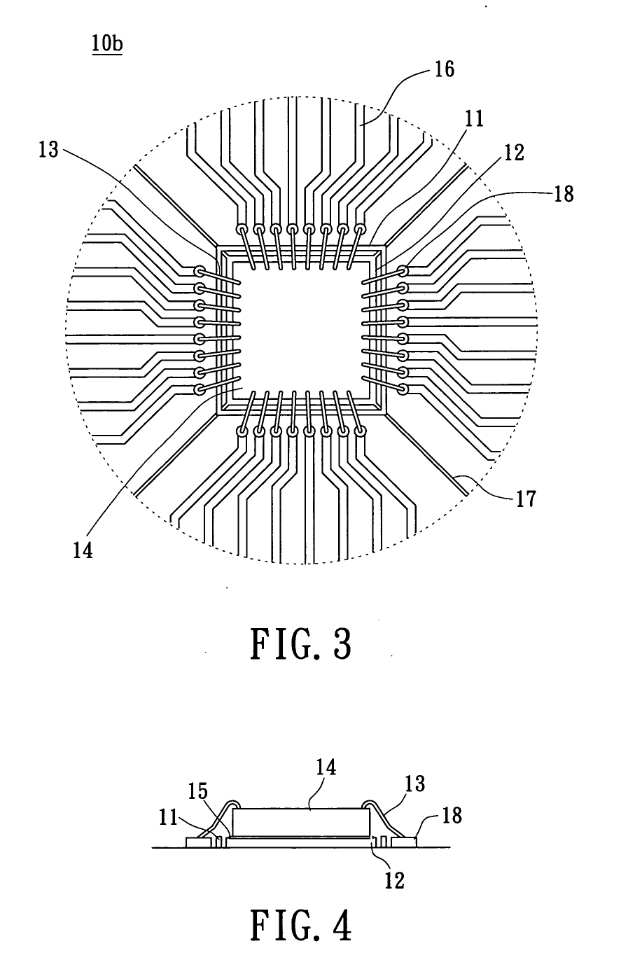

FIG. 3 is a partially top view of a semiconductor package according to one embodiment of the invention. A package substrate 10b has a die pad 12, a plurality of traces 16, a plurality of gold contacts 18 and an adhesive dike 11. The die pad 12 is an electrically conductive sheet connected to a reference voltage 17. The traces 16 are distributed around the die pad 12. A chip 14 is attached on the die pad 12 and connects to the gold contacts 18 via wires 13. The gold contacts 18 are formed on the die pad 12 for electrically connecting to the chip 14. The adhesive dike 11 is formed between the die pad 12 and the traces 16. Specifically, the adhesive dike 11 is formed around the die pad 12 in a continuous or discontinuous manner.

FIG. 4 is a cross-sectional view of FIG. 3. In an integrated circuit packaging, the chip 14 is attached onto the die pad 12 of the substrate 10b via an adhesive 15. The adhesive 15 is preferably an epoxy resin. When the integrated chip 14 is fixed on the die pad 12, a circuit of the chip 14 connects to the gold contacts 18 on the substrate 12 via the wires 13 by wire bonding technology. The electrical conductivity of the wires 13 allows electrical connection between the circuit of the chip 14 and the substrate 10b.

While the chip 14 is attached onto the die pad 12, the adhesive 15 is often applied on the die pad 12 and is blanketed with a heated nitrogen. The adhesive 15 always flows out of the die pad 12, adversely affecting the conductivity of the gold contacts 18 and the reliability of the packaging.

In the invention, the arrangement of the adhesive dikes prevents the adhesive 15 from flowing out of the die pad 12, so that the conductivity of the gold contacts 18 and the reliability of the packaging are not adversely affected.

As described above, the adhesive dikes 11 around the die pad 12 can effectively prevent the adhesive 15 from flowing out of the die pad during chip attachment, and thus prevent the reliability of the semiconductor from being reduced.

It should be apparent to those skilled in the art that the above description is only illustrative of specific embodiments and examples of the invention, and should not be construed in a limiting way. Therefore, the invention should cover various modifications and variations made to the herein-described structure and operations of the invention, provided they fall within the scope of the invention as defined in the following appended claims.

1. A package substrate having a chip on a substrate, the substrate comprising:
a die pad on the substrate, wherein the chip is attached on the die pad via an adhesive, and a plurality of gold contacts are distributed on the die pad for electrically connecting to the chip;
a plurality of traces, distributed around the die pad, wherein each trace has a gold contact at a tip thereof to connect to the chip via wires; and
an adhesive dike, formed between the die pad and the traces to prevent the adhesive from flowing out of the die pad when the chip is attached on the die pad.

2. The packaging substrate of claim 1, wherein the adhesive dike is formed around the die pad in a continuous manner.

3. The packaging substrate of claim 1, wherein the adhesive dike is formed around the die pad in a discontinuous manner.

4. The packaging substrate of claim 1, wherein the die pad is an electrically conductive sheet connected to a reference voltage.

5. The packaging substrate of claim 1, wherein the adhesive is an epoxy resin.
